(19) United States
(12) Patent Application Publication
(10) Pub. No.: US 2026/0171154 A1
(43) Pub. Date: Jun. 18, 2026

(54) MEMORY DEVICE

(71) Applicant: SK hynix Inc., Icheon-si Gyeonggi-do (KR)

(72) Inventor: Hee Youl LEE, Icheon-si Gyeonggi-do (KR)

(73) Assignee: SK hynix Inc., Icheon-si Gyeonggi-do (KR)

(21) Appl. No.: 19/219,691

(22) Filed: May 27, 2025

(30) Foreign Application Priority Data
Dec. 12, 2024 (KR) 10-2024-0185083

(51) Int. Cl. G11C 16/04; G11C 5/06; G11C 16/10

(52) U.S. Cl. CPC G11C 16/0483; G11C 5/063; G11C 16/10

(57) ABSTRACT

A memory device includes strings, a control circuit, and a peripheral circuit. Each of the strings comprises a drain selection transistor, a source selection transistor, a plurality of memory cell groups disposed between the drain selection transistor and the source selection transistor, and intermediate portions disposed between the plurality of memory cell groups. The control circuit determines a selected memory cell group that includes a target memory cell and one or more non-selected memory cell groups. The peripheral circuit applies an intermediate selection voltage to first intermediate selection lines coupled to first intermediate selection transistors adjacent to one or both ends of each of the non-selected memory cell groups, and applies a first pass voltage to second intermediate selection lines coupled to second intermediate selection transistors adjacent to one or both ends of the selected memory cell group.

### CROSS-REFERENCES TO RELATED APPLICATION

The present application claims priority under 35 U.S.C. §119(a) to Korean Patent application number 10-2024-0185083 filed in the Korean Intellectual Property Office on Dec. 12, 2024, which application is incorporated herein by reference in its entirety.

### BACKGROUND

1. Technical Field

Various embodiments generally relate to a memory device.
2. Related Art

A semiconductor device is a key component of electronic devices and has a wide range of modern applications, for example, it can be utilized in technologies such as computing, communications, artificial intelligence, and memory. The semiconductor device may consist of components like transistors, diodes, integrated circuits (ICs).

While a memory device, which is a type of semiconductor device, is performing a program operation, it may encounter a disturbance phenomenon in which stored data is interfered with and corrupted. To reduce the disturbance phenomenon and increase the stability and reliability of memory cells, dummy word lines may be arranged. However, increasing the number of dummy word lines may be disadvantageous in terms of manufacturing cost, power consumption, memory capacity, etc. Therefore, there may be a need for a method that can effectively suppress the disturbance phenomenon with a small number of dummy word lines.

### SUMMARY

In an embodiment, a memory device may include strings, a control circuit, and a peripheral circuit. The strings may be coupled between a bit line and a source line. Each of the strings may include a drain selection transistor coupled to the bit line, a source selection transistor coupled to the source line, a plurality of memory cell groups disposed between the drain selection transistor and the source selection transistor, and one or more intermediate portions disposed between the plurality of memory cell groups. Each of the one or more intermediate portions may include a plurality of intermediate selection transistors coupled in series between adjacent memory cell groups. The control circuit may be configured to determine, among memory cell groups included in a selected string, a selected memory cell group that includes a target memory cell in which a program operation is to be performed, and one or more non-selected memory cell groups that are not the selected memory cell group. The selected string may be a string that includes the target memory cell among the strings. The peripheral circuit may be configured to operate under control of the control circuit, may be configured to apply an intermediate selection voltage to one or more first intermediate selection lines coupled to one or more first intermediate selection transistors adjacent to one or both ends of each of the one or more non-selected memory cell groups, and may be configured to apply a first pass voltage to one or more second intermediate selection lines coupled to one or more second intermediate selection transistors adjacent to one or both ends of the selected memory cell group.

In an embodiment, a memory device may include strings, a control circuit, and a peripheral circuit. Each of the strings may include a drain selection transistor coupled to the bit line, a source selection transistor coupled to the source line, a plurality of memory cell groups disposed between the drain selection transistor and the source selection transistor, and one or more intermediate portions disposed between the plurality of memory cell groups. Each of the plurality of memory cell groups may include a plurality of memory cells coupled in series and one or more dummy memory cells disposed at one or both ends of the plurality of memory cells. Each of the one or more intermediate portions may include a plurality of intermediate selection transistors coupled in series between adjacent memory cell groups. The control circuit may be configured to determine, among memory cell groups included in a selected string, a selected memory cell group that includes a target memory cell in which a program operation is to be performed, and one or more non-selected memory cell groups that are not the selected memory cell group. The selected string may be a string that includes the target memory cell among the strings. The peripheral circuit may be configured to operate under control of the control circuit, may be configured to apply an intermediate selection voltage to one or more first intermediate selection lines coupled to one or more first intermediate selection transistors adjacent to one or both ends of each of the one or more non-selected memory cell groups, and may be configured to apply a first pass voltage to one or more first dummy word lines coupled to one or more first dummy memory cells included in the one or more non-selected memory cell groups.

In an embodiment, a memory device may include strings, a control circuit, and a peripheral circuit. Each of the strings may include a drain selection transistor coupled to the bit line, a source selection transistor coupled to the source line, a plurality of memory cell groups disposed between the drain selection transistor and the source selection transistor, and one or more intermediate portions disposed between the plurality of memory cell groups. Each of the plurality of memory cell groups may include a plurality of memory cells coupled in series and one or more dummy memory cells disposed at one or both ends of the plurality of memory cells. Each of the one or more intermediate portions may include a plurality of intermediate selection transistors coupled in series between adjacent memory cell groups. The control circuit may be configured to determine, among memory cell groups included in a selected string, a selected memory cell group that includes a target memory cell in which a program operation is to be performed, and one or more non-selected memory cell groups that are not the selected memory cell group. The selected string may be a string that includes the target memory cell among the strings. The peripheral circuit may be configured to operate under control of the control circuit, may be configured to apply a first pass voltage to one or more intermediate selection lines coupled to one or more intermediate selection transistors adjacent to one or both ends of the selected memory cell group, and may be configured to apply a second pass voltage higher than the first pass voltage to one or more dummy word lines coupled to one or more dummy memory cells included in the selected memory cell group.

### BRIEF DESCRIPTION OF THE DRAWINGS

FIG. 1 is a block diagram illustrating a memory device according to an embodiment of the present disclosure.

FIG. 2 is a circuit diagram illustrating strings according to an embodiment of the present disclosure.

FIG. 3 is a diagram illustrating voltages applied to row lines and a channel of a non-selected string in a program operation according to an embodiment of the present disclosure.

FIG. 4 is a timing diagram of an embodiment of a program operation in which a second stack is a selected stack as in the example of FIG. 3.

FIG. 5 is a diagram illustrating voltages applied to row lines and a channel of non-selected string in a program operation according to an embodiment of the present disclosure.

FIG. 6 is a timing diagram of an embodiment of a program operation in which a third stack is a selected stack as in the example of FIG. 5.

FIG. 7 is a flowchart illustrating operation of a memory device according to an embodiment of the present disclosure.

### DETAILED DESCRIPTION

Hereinafter, embodiments of the present disclosure will be described below with reference to the accompanying drawings. For some embodiments, terms such as “first,” “second,” etc., are used to distinguish between various elements and do not imply size, order, priority, quantity, or importance of the elements. For example, a first element may be named as a second element in one example, and the second element may be named as a first element in another example.

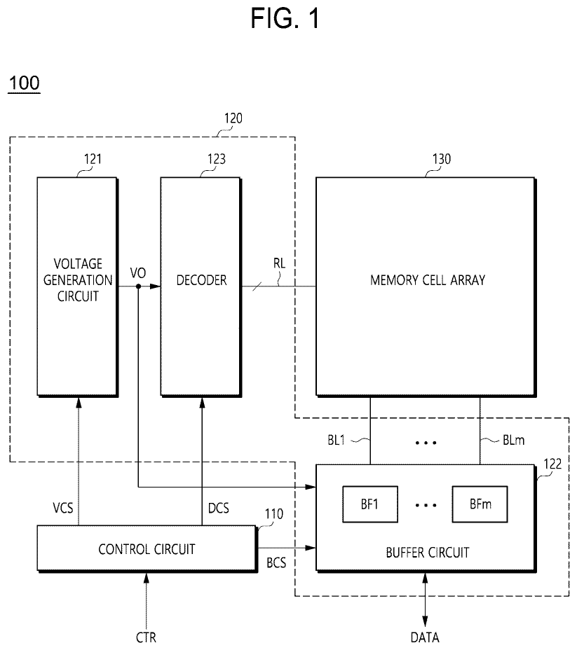

FIG. 1 is a block diagram illustrating a memory device 100 according to an embodiment of the present disclosure.

Referring to FIG. 1, the memory device 100 may operate in response to a control signal CTR from an external controller (not shown). The memory device 100 may store data DATA received from a controller by performing a program operation, and may output the stored data DATA to the controller by performing a read operation.

The memory device 100 may include a control circuit 110, a peripheral circuit 120, and a memory cell array 130.

The control circuit 110 may control operation of a voltage generation circuit 121, a buffer circuit 122, and a decoder 123 to perform memory cell operations, such as program operations, read operations, erase operations, and the like, under control of the controller. For example, to control the voltage generation circuit 121, the control circuit 110 may generate a voltage control signal VCS and output it to the voltage generation circuit 121. To control the buffer circuit 122, the control circuit 110 may generate a buffer control signal BCS and output to the buffer circuit 122. To control the decoder 123, the control circuit 110 may generate a decoder control signal DCS and output to the decoder 123. In an embodiment, the control circuit 110 may operate in response to a control signal CTR from an external controller (not shown).

The peripheral circuit 120 may store data in the memory cell array 130 and read data from the memory cell array 130 under control of the control circuit 110. The peripheral circuit 120 may include the voltage generation circuit 121, the buffer circuit 122, and the decoder 123.

The voltage generation circuit 121 may generate various operating voltages VO in response to the voltage control signal VCS, and may pass the operating voltages VO to the decoder 123 and the buffer circuit 122.

The buffer circuit 122 may be coupled to the memory cell array 130 through bit lines BL1 to BLi. The buffer circuit 122 may include sub-buffers BF1 to BFi coupled to the bit lines BL1 to BLi, respectively. The sub-buffers BF1 to BFi may be coupled with memory cells (not shown) included in the memory cell array 130 through the bit lines BL1 to BLi. The sub-buffers BF1 to BFi may receive and store data to be stored in the memory cells from the controller. The sub-buffers BF1 to BFi may store data read from the memory cells for output to the controller. The sub-buffers BF1 to BFi may operate simultaneously in response to the buffer control signal BCS, such that the memory cells coupled with the bit lines BL1 to BLi, respectively, may be accessed simultaneously. The words “simultaneous” and “simultaneously” as used herein with respect to processes mean that the processes take place on overlapping intervals of time. For example, if a first process takes place over a first interval of time and a second process takes place simultaneously over a second interval of time, then the first and second intervals at least partially overlap each other such that there exists a time at which the first and second processes are both taking place.

The decoder 123 may be coupled to the memory cell array 130 through row lines RL. The decoder 123 may apply operating voltages VO to the row lines RL in response to the decoder control signal DCS. The row lines RL may include a drain selection line, intermediate dummy word lines, word lines, and a source selection line, as will be described later.

The memory cell array 130 may include memory cells in which data DATA is stored. The memory cells may be selectively accessed through the row lines RL and the bit lines BL1 to BLi.

The memory cell array 130 may include a plurality of strings (not shown) coupled between a bit line and a source line. Each of the plurality of strings may include a drain selection transistor coupled with the bit line, a source selection transistor coupled with the source line, a plurality of memory cell groups disposed between the drain selection transistor and the source selection transistor, and one or more intermediate portions disposed between the plurality of memory cell groups. Each of the plurality of memory cell groups may include a plurality of memory cells coupled in series, and one or more dummy memory cells disposed at one or both ends of the plurality of memory cells. Each of the one or more intermediate portions may include a plurality of intermediate selection transistors coupled in series between adjacent memory cell groups. Each of the one or more dummy memory cells may couple memory cells with an adjacent intermediate selection transistor, the drain selection transistor, or the source selection transistor.

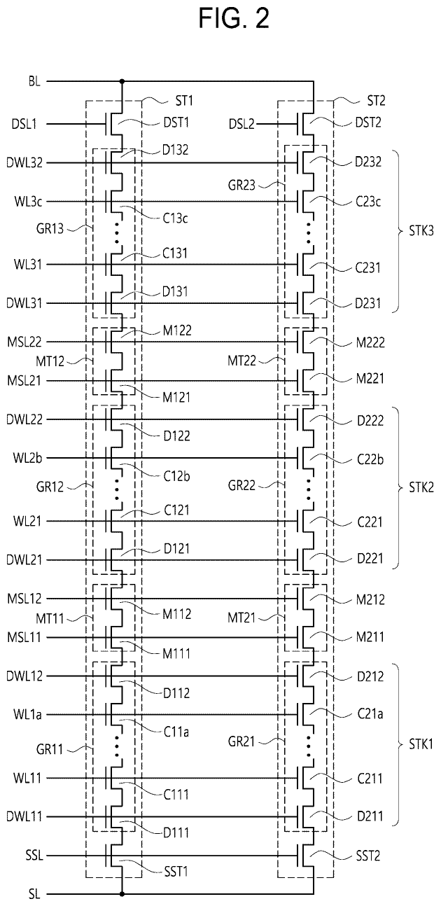

FIG. 2 is a circuit diagram illustrating strings ST1, ST2 according to an embodiment of the present disclosure. The number of each configuration shown in FIG. 2 may be for an example.

Referring to FIG. 2, the strings ST1, ST2 may be coupled between a bit line BL and a source line SL.

The string ST1 may include a drain selection transistor DST1 coupled with the bit line BL, a source selection transistor SST1 coupled with the source line SL, memory cell groups GR11, GR12, GR13 disposed between the drain selection transistor DST1 and the source selection transistor SST1, and intermediate portions MT11, MT12 disposed between the memory cell groups GR11, GR12, GR13. The memory cell groups GR11, GR12, GR13 and the intermediate portions MT11, MT12 may be coupled in series between the drain selection transistor DST1 and the source selection transistor SST1.

The memory cell group GR11 may include memory cells C111 to C11a coupled in series and dummy memory cells D111, D112 disposed at both ends of the memory cells C111 to C11a. The memory cells C111 to C11a may be coupled to word lines WL11 to WL1a, respectively. The dummy memory cells D111, D112 may be coupled to dummy word lines DWL11, DWL12, respectively. The dummy memory cell D111 may couple the adjacent source selection transistor SST1 and the memory cell C111. The dummy memory cell D112 may couple the memory cell C11a with an adjacent intermediate selection transistor M111. In an embodiment, a plurality of dummy memory cells coupled in series may be disposed at each end of the memory cells C111 to C11a, rather than a single dummy memory cell as shown. In an embodiment, the memory cell group GR11 might not include the dummy memory cells D111, D112.

Each of the memory cell groups GR12, GR13 may be configured similarly to the memory cell group GR11. The memory cell group GR12 may include memory cells C121 to C12b coupled with word lines WL21 to WL2b and dummy memory cells D121, D122 coupled with dummy word lines DWL21, DWL22. The memory cell group GR13 may include memory cells C131 to C13c coupled with word lines WL31 to WL3c and dummy memory cells D131, D132 coupled with dummy word lines DWL31, DWL32.

The intermediate portion MT11 may include intermediate selection transistors M111, M112 coupled in series between adjacent memory cell groups GR11, GR12. The intermediate selection transistors M111, M112 may be coupled to intermediate selection lines MSL11, MSL12, respectively. In an embodiment, the intermediate portion MT11 may include three or more intermediate selection transistors coupled in series, rather than two intermediate selection transistors M111, M112 as shown.

The intermediate portion MT12 may be configured similarly to the intermediate portion MT11. The intermediate portion MT12 may include intermediate selection transistors M121, M122 coupled to intermediate selection lines MSL21, MSL22.

The drain selection transistor DST1 may be coupled to a drain selection line DSL1. The source selection transistor SST1 may be coupled to a source selection line SSL.

The string ST2 may be configured similarly to the string ST1. A drain selection transistor DST2 included in the string ST2 may be coupled to a drain selection line DSL2. Thus, the strings ST1, ST2 may be individually selected through control of the drain selection lines DSL1, DSL2. The memory cells included in the strings ST1, ST2 may be coupled in common to word lines WL11 to WL1a, WL21 to WL2b, WL31 to WL3c. The memory cells that are located at relatively corresponding positions in the strings ST1, ST2 may be coupled to the same word line. The dummy memory cells included in strings ST1, ST2 may be coupled in common to dummy word lines DWL11, DWL12, DWL21, DWL22, DWL31, DWL32. The dummy memory cells that are located at relatively corresponding positions in the strings ST1, ST2 may be coupled to the same dummy word line. The intermediate selection transistors included in strings ST1, ST2 may be coupled in common to intermediate selection lines MSL11, MSL12, MSL21, MSL22. The intermediate selection transistors that are located at relatively corresponding positions in the strings ST1, ST2 may be coupled to the same intermediate selection line. The source selection transistors SST1, SST2 included in the strings ST1, ST2 may be coupled in common to the source selection line SSL.

The bit line BL may be any one of the bit lines BL1 to BLm of FIG. 1. A plurality of strings may be coupled between the bit lines BL1 to BLm and the source line SL in a manner similar to the strings ST1 and ST2. Among the plurality of strings coupled to the bit lines BL1 to BLm, strings corresponding to the string ST1 may be coupled in common to the drain selection line DSL1. Among the plurality of strings coupled to the bit lines BL1 to BLm, strings corresponding to the string ST2 may be coupled in common to the drain selection line DSL2. The plurality of strings coupled to the bit lines BL1 to BLm may be coupled in common to the word lines WL11 to WL1a, WL21 to WL2b, WL31 to WL3c, the dummy word lines DWL11, DWL12, DWL21, DWL22, DWL31, DWL32, the intermediate selection lines MSL11, MSL12, MSL21, MSL22, and the source selection line SSL.

A stack may refer to a layer formed by memory cell groups disposed at the same height when the word line groups GR11, GR12, GR13, GR21, GR22, GR23 in the strings ST1, ST2 are stacked. The memory cell groups GR11, GR21 may be included in a first stack STK1, the memory cell groups GR12, GR22 may be included in a second stack STK2, and the memory cell groups GR13, GR23 may be included in a third stack STK3. The memory cell groups included in the same stack may be coupled to the same word lines in common.

A target memory cell may be a memory cell where a program operation is to be performed. A target word line may be a word line to which the target memory cell is coupled. A selected string may be a string including the target memory cell among a plurality of strings coupled to any bit line. A selected memory cell group may be a memory cell group that includes the target memory cell among memory cell groups included in the selected string. A non-selected memory cell group may be a memory cell group that does not contain the target memory cell among the memory cell groups included in the selected string. A non-selected string may be a string that is not the selected string among a plurality of strings coupled to the same bit line as the selected string. A selected stack may be a stack containing the selected memory cell group. A non-selected stack may be a stack containing the non-selected memory cell group.

For example, in FIG. 2, when the target memory cell is the memory cell C111, the target word line is the word line WL11, the selected string is the string ST1, and the selected memory cell group is the memory cell group GR11, the non-selected memory cell groups are the memory cell groups GR12, GR13, the non-selected string is the string ST2, the selected stack is the first stack STK1, and the non-selected stacks may be the second and third stacks STK2, STK3.

Referring again to FIG. 1, the control circuit 110 may determine, for each of the bit lines BL1 to BLm, among memory cell groups included in a selected string, a selected memory cell group that includes a target memory cell in which a program operation is to be performed, and one or more non-selected memory cell groups that are not the selected memory cell group.

The peripheral circuit 120 may perform a program operation under control of the control circuit 110. Specifically, the decoder 123 may apply an intermediate selection voltage to one or more first intermediate selection lines coupled to one or more first intermediate selection transistors adjacent one or both ends of each of one or more non-selected memory cell groups. The intermediate selection voltage may be a voltage that turns off one or more third intermediate selection transistors coupled to the one or more first intermediate selection lines and included in one or more non-selected strings, and turns on the first intermediate selection transistors. In an embodiment, the decoder 123 may apply the intermediate selection voltage at different levels to each of one or more first intermediate selection lines.

The decoder 123 may apply a first pass voltage to one or more second intermediate selection lines coupled to one or more second intermediate selection transistors adjacent to one or both ends of a selected memory cell group.

The decoder 123 may apply the first pass voltage to one or more first dummy word lines coupled to one or more first dummy memory cells included in one or more non-selected memory cell groups.

The decoder 123 may apply a second pass voltage higher than the first pass voltage to one or more second dummy word lines coupled to one or more second dummy memory cells included in a selected memory cell group.

The decoder 123 may apply a third pass voltage higher than the first pass voltage to first word lines coupled to first memory cells included in one or more non-selected memory cell groups.

The decoder 123 may apply a fourth pass voltage higher than the third pass voltage to second word lines coupled to second memory cells that are not a target memory cell among memory cells included in a selected memory cell group.

The decoder 123 may apply a program voltage to a target word line coupled to a target memory cell.

According to an embodiment of the present disclosure, by controlling voltages of respective intermediate selection lines and dummy word lines according to the position of a selected memory cell group or a selected stack, the disturbance phenomenon can be effectively suppressed with fewer dummy word lines.

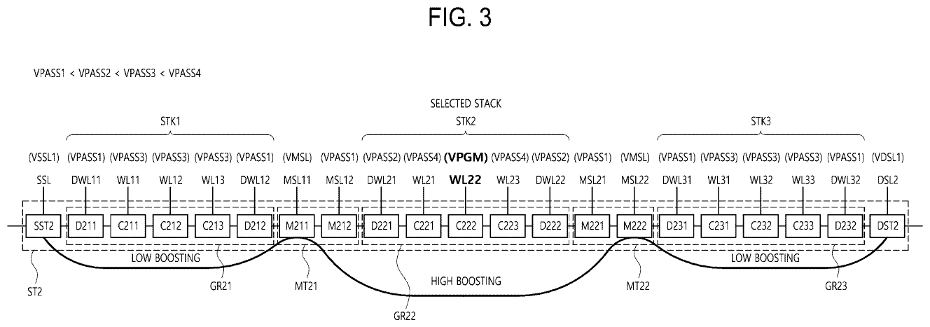

FIG. 3 is a diagram illustrating voltages applied to the row lines RL and a channel of a non-selected string ST2 in a program operation according to an embodiment of the present disclosure. The number of each configuration shown in FIG. 3 may be for an example.

Referring to FIG. 3, a target word line may be a word line WL22 and a target memory cell may be a memory cell coupled to the target word line WL22 and included the selected string ST1. Accordingly, a second stack STK2 to which the target word line WL22 is coupled may be a selected stack. First and third stacks STK1, STK3 may be non-selected stacks.

In a program operation, an intermediate selection voltage VMSL may be applied to intermediate selection lines MSL11, MSL22 (i.e., first intermediate selection lines) coupled to intermediate selection transistors M211, M222. The intermediate selection voltage VMSL may be a voltage that turns off the intermediate selection transistors M211, M222. Thus, the intermediate selection transistors M211, M222 may disconnect a channel between the memory cell groups GR21 to GR23 in response to the intermediate selection voltage VMSL. The intermediate selection lines MSL11, MSL22 may be coupled to adjacent intermediate selection transistors M111, M122 (i.e., first intermediate selection transistors) at one or both ends of each of non-selected memory cell groups GR11, GR13 in the selected string ST1. The intermediate selection lines MSL11, MSL22 may also be described as intermediate selection lines adjacent to one or both ends of each of the non-selected stacks Stk1, Stk3.

Further, a first pass voltage VPASS1 may be applied to dummy word lines DWL11, DWL12, DWL31, DWL32 (i.e., first dummy word lines) coupled to dummy memory cells D211, D212, D231, D232. The dummy word lines DWL11, DWL12, DWL31, DWL32 may be coupled with dummy memory cells D111, D112, D131, D132 (i.e., first dummy memory cells) included in non-selected memory cell groups GR11, GR13 in the selected string ST1. The dummy word lines DWL11, DWL12, DWL31, DWL32 may also be described as dummy word lines coupled to the non-selected stacks STK1, STK3.

Further, a third pass voltage VPASS3 may be applied to word lines WL11-WL13, WL31-WL33 (i.e., first word lines) coupled to memory cells C211-C213, C231-C233. The word lines WL11 to WL13, WL31 to WL33 may be coupled with memory cells (i.e., first memory cells) included in non-selected memory cell groups GR11, GR13 in the selected string ST1. The word lines WL11 to WL13, WL31 to WL33 may also be described as word lines coupled to the non-selected stacks STK1, STK3.

Further, the first pass voltage VPASS1 may be applied to intermediate selection lines MSL12, MSL21 (i.e., second intermediate selection lines) coupled to intermediate selection transistors M212, M221. The intermediate selection lines MSL12, MSL21 may be coupled to intermediate selection transistors M112, M121 (i.e., second intermediate selection transistors) adjacent to both ends of the selected memory cell group GR12 in the selected string ST1. The intermediate selection lines MSL12, MSL21 may also be described as intermediate selection lines adjacent both ends of the selected stack STK2.

Further, a second pass voltage VPASS2 may be applied to dummy word lines DWL21, DWL22 (i.e., second dummy word lines) coupled to dummy memory cells D221, D222. The dummy word lines DWL21, DWL22 may be coupled with dummy memory cells D121, D122 (i.e., second dummy memory cells) included in the selected memory cell group GR12 of the selected string ST1. The dummy word lines DWL21, DWL22 may also be described as dummy word lines coupled to the selected stack STK2..

Further, a fourth pass voltage VPASS4 may be applied to word lines WL21, WL23 (i.e., second word lines) coupled to memory cells C221, C223. The word lines WL21, WL23 may be coupled to memory cells (i.e., second memory cells) that are not the target memory cell among memory cells included in the selected memory cell group GR12 in the selected string ST1. The word lines WL21, WL23 may also be described as word lines coupled to the selected stack STK2.

The first pass voltage VPASS1 to the fourth pass voltage VPASS4 may be voltages that turn on the memory cells and the dummy memory cells. The first pass voltage VPASS1 may be lower than the second pass voltage VPASS2, the second pass voltage VPASS2 may be lower than the third pass voltage VPASS3, and the third pass voltage VPASS3 may be lower than the fourth pass voltage VPASS4.

Further, a source non-selected voltage VSSL1 may be applied to the source selection line SSL coupled to the source selection transistor SST2. The source non-selected voltage VSSL1 may be a voltage that turns off the source selection transistor SST2. Further, a drain non-selected voltage VDSL1 may be applied to the drain selection line DSL2 coupled to the drain selection transistor DST2. The drain non-selected voltage VDSL1 may be a voltage that turns off the drain selection transistor DST2.

Further, a program voltage VPGM may be applied to the target word line WL22.

Thus, in an embodiment, a channel potential of the memory cell group GR22 may be boosted to a high voltage level, and disturbance phenomenon caused by the program voltage VPGM may be suppressed. Further, in an embodiment, channel potentials of the memory cell groups GR21, GR23 may be boosted to a low voltage level, and disturbance phenomenon caused by the third pass voltage VPASS3 may be suppressed. Here, in an embodiment, the relatively low levels of the first pass voltage VPASS1 and the second pass voltage VPASS2 can mitigate the electric field caused by the nearby the third pass voltage VPASS3 and the fourth pass voltage VPASS4. At this time, in an embodiment, the intermediate selection lines MSL12, MSL21 may act similarly to the dummy word lines DWL12, DWL31 to alleviate the channel potential. As a result, in an embodiment, disturbance phenomenon may be effectively suppressed with only a small number of dummy word lines.

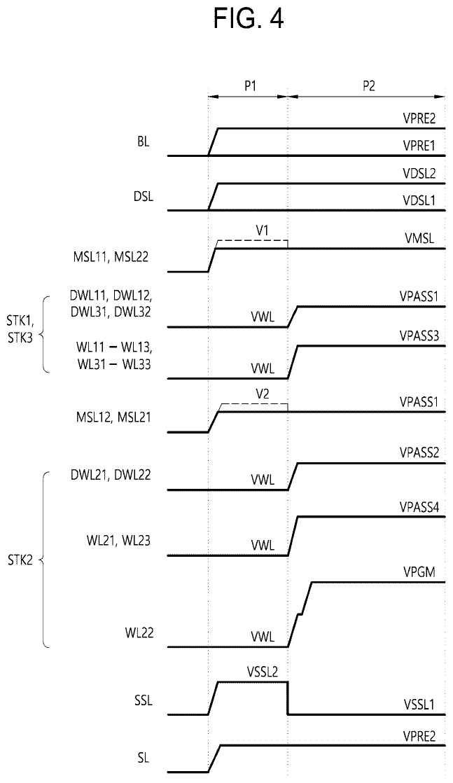

FIG. 4 is a timing diagram of a program operation in which the second stack STK2 is a selected stack as in the example of FIG. 3.

Referring to FIG. 4, the program operation may include a first interval P1 and a second interval P2. The first interval P1 may be a channel precharge interval, and the second interval P2 may be a program interval.

In the first interval P1, a first precharge voltage VPRE1 or a second precharge voltage VPRE2 higher than the first precharge voltage VPRE1 may be applied to each bit line BL. Specifically, the first precharge voltage VPRE1 may be applied to a bit line BL coupled to a target memory cell to be programmed. The second precharge voltage VPRE2 may be applied to a bit line BL coupled to a target memory cell that has been programmed. In an embodiment, a third precharge voltage (not shown) that is higher than the first precharge voltage VPRE1 and lower than the second precharge voltage VPRE2 may be applied to a bit line BL coupled to a target memory cell that is to be weakly programmed.

Additionally, a drain selection voltage VDSL2 or a drain non-selected voltage VDSL1 may be applied to each drain selection line DSL. Specifically, the drain selection voltage VDSL2 may be applied to a drain selection line DSL1 coupled to the selected string ST1 including a target memory cell. The drain selection voltage VDSL2 may be a voltage capable of turning on a drain selection transistor of each string. The drain non-selected voltage VDSL1 may be applied to a drain selection line DSL2 coupled to the non-selected string ST2 that does not contain a target memory cell.

Additionally, the intermediate selection voltage VMSL may be applied to the intermediate selection lines MSL11, MSL22 adjacent to one or both ends of each of the non-selected stacks STK1, STK3. The intermediate selection voltage VMSL may be a voltage that turns off the intermediate selection transistors M211, M222 included in the non-selected string ST2. The intermediate selection transistors M111, M122 coupled to the intermediate selection lines MSL11, MSL22 in the selected string ST1 may be turned on in response to the intermediate selection voltage VMSL. In an embodiment, a voltage V1 higher than the intermediate selection voltage VMSL may be applied to the intermediate selection lines MSL11, MSL22 in the first interval P1.

Further, the first pass voltage VPASS1 may be applied to the intermediate selection lines MSL12, MSL21 adjacent to both ends of the selected stack STK2. In an embodiment, a voltage V2 higher than the first pass voltage VPASS1 may be applied to the intermediate selection lines MSL12, MSL21 in the first interval P1.

In addition, a source selection voltage VSSL2 may be applied to the source selection line SSL. The source selection voltage VSSL2 may be a voltage capable of turning on a source selection transistor of each string. Additionally, the second precharge voltage VPRE2 may be applied to the source line SL.

In the first interval P1, a first word line voltage VWL may be applied to all of the word lines WL11 to WL13, WL21 to WL23, WL31 to WL33, and the dummy word lines DWL11, DWL12, DWL21, DWL22, DWL31, DWL32. In an embodiment, the first word line voltage VWL may be a ground voltage.

In the second interval P2, the source non-selected voltage VSSL1 may be applied to the source selection line SSL.

Further, the first pass voltage VPASS1 may be applied to the dummy word lines DWL11, DWL12, DWL31, DWL32 coupled to the non-selected stacks STK1, STK3. Additionally, the third pass voltage VPASS3 may be applied to the word lines WL11 to WL13, WL31 to WL33 coupled to the non-selected stacks STK1, STK3.

Additionally, the second pass voltage VPASS2 may be applied to the dummy word lines DWL21, DWL22 coupled to the selected stack STK2. Further, the fourth pass voltage VPASS4 may be applied to the remaining word lines WL21, WL23 that are not the target word line WL22 coupled to the selected stack STK2. Further, an intermediate voltage, e.g., the fourth pass voltage VPASS4, may be applied to the target word line WL22, and the program voltage VPGM may be applied after a predetermined time. The word “predetermined” as used herein with respect to a parameter, such as a predetermined timing, time, or voltage level, means that a value for the parameter is determined prior to the parameter being used in a process or algorithm. For some embodiments, the value for the parameter is determined before the process or algorithm begins. In other embodiments, the value for the parameter is determined during the process or algorithm but before the parameter is used in the process or algorithm.

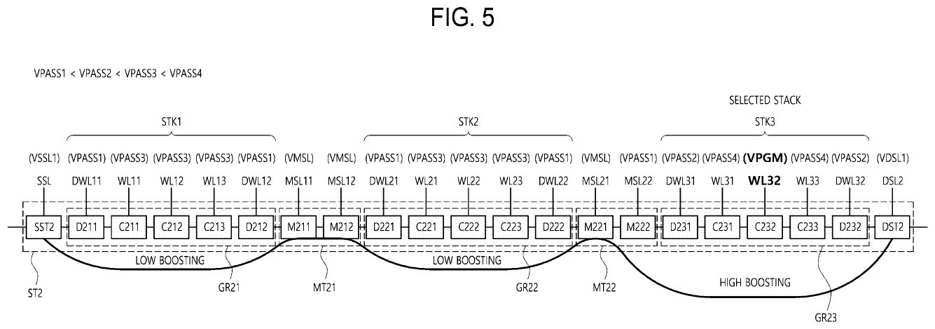

FIG. 5 is a diagram illustrating voltages applied to the row lines RL and a channel of a non-selected string ST2 in a program operation according to an embodiment of the present disclosure. The number of each configuration shown in FIG. 5 may be for an example.

Referring to FIG. 5, a target word line may be a word line WL32 and a target memory cell may be a memory cell coupled to the target word line WL32 and included the selected string ST1. Accordingly, a third stack STK3 to which the target word line WL32 is coupled may be a selected stack. First and second stacks STK1, STK2 may be non-selected stacks.

In a program operation, an intermediate selection voltage VMSL may be applied to intermediate selection lines MSL11, MSL12, MSL21 (i.e., first intermediate selection lines) coupled to intermediate selection transistors M211, M212, M221. The intermediate selection voltage VMSL may be a voltage that turns off the intermediate selection transistors M211, M212, M221. Thus, the intermediate selection transistors M211, M212, M221 may disconnect a channel between the memory cell groups GR21 to GR23 in response to the intermediate selection voltage VMSL. The intermediate selection lines MSL11, MSL12, MSL21 may be coupled to adjacent intermediate selection transistors M111, M112, M121 (i.e., first intermediate selection transistors) at one or both ends of each of non-selected memory cell groups GR11, GR12 in the selected string ST1. The intermediate selection lines MSL11, MSL12, MSL21 may also be described as intermediate selection lines adjacent to one or both ends of each of the non-selected stacks STK1, STK2.

Further, a first pass voltage VPASS1 may be applied to dummy word lines DWL11, DWL12, DWL21, DWL22 (i.e., first dummy word lines) coupled to dummy memory cells D211, D212, D221, D222. The dummy word lines DWL11, DWL12, DWL21, DWL22 may be coupled with dummy memory cells D111, D112, D121, D122 (i.e., first dummy memory cells) included in non-selected memory cell groups GR11, GR12 in the selected string ST1. The dummy word lines DWL11, DWL12, DWL21, DWL22 may also be described as dummy word lines coupled to the non-selected stacks STK1, STK2.

Further, a third pass voltage VPASS3 may be applied to word lines WL11 to WL13, WL21 to WL23 (i.e., first word lines) coupled to memory cells C211 to C213, C221 to C223. The word lines WL11 to WL13, WL21 to WL23 may be coupled with memory cells (i.e., first memory cells) included in non-selected memory cell groups GR11, GR12 in the selected string ST1. The word lines WL11 to WL13, WL21 to WL23 may also be described as word lines coupled to the non-selected stacks STK1 and STK2.

Further, the first pass voltage VPASS1 may be applied to an intermediate selection line MSL22 (i.e., a second intermediate selection line) coupled to an intermediate selection transistor M222. The intermediate selection line MSL22 may be coupled to an intermediate selection transistor M122 (i.e., a second intermediate selection transistor) adjacent to one end of the selected memory cell group GR13 in the selected string ST1. The intermediate selection line MSL22 may also be described as an intermediate selection line adjacent to one end of the selected stack STK3.

Further, a second pass voltage VPASS2 may be applied to dummy word lines DWL31, DWL32 (i.e., second dummy word lines) coupled to dummy memory cells D231, D232. The dummy word lines DWL31, DWL32 may be coupled with dummy memory cells D131, D132 (i.e., second dummy memory cells) included in the selected memory cell group GR13 of the selected string ST1. The dummy word lines DWL31, DWL32 may also be described as dummy word lines coupled to the selected stack STK3.

Further, a fourth pass voltage VPASS4 may be applied to word lines WL31, WL33 (i.e., second word lines) coupled to memory cells C231, C233. The word lines WL31, WL33 may be coupled to memory cells (i.e., second memory cells) that are not a target memory cell among memory cells included in the selected memory cell group GR13 of the selected string ST1. The word lines WL31, WL33 may also be described as word lines coupled to the selected stack STK3.

Further, a source non-selected voltage VSSL1 may be applied to the source selection line SSL coupled to the source selection transistor SST2. The source non-selected voltage VSSL1 may be a voltage that turns off the source selection transistor SST2. Further, a drain non-selected voltage VDSL1 may be applied to the drain selection line DSL2 coupled to the drain selection transistor DST2. The drain non-selected voltage VDSL1 may be a voltage that turns off the drain selection transistor DST2.

Further, a program voltage VPGM may be applied to the target word line WL32.

Thus, in an embodiment, a channel potential of the memory cell group GR23 may be boosted to a high voltage level, and disturbance phenomenon caused by the program voltage VPGM may be suppressed. Further, in an embodiment, channel potentials of the memory cell groups GR21, GR22 may be boosted to a low voltage level, and disturbance phenomenon caused by the third pass voltage VPASS3 may be suppressed. Here, in an embodiment, the relatively low levels of the first pass voltage VPASS1 and the second pass voltage VPASS2 can mitigate the electric field caused by the nearby the third pass voltage VPASS3 and the fourth pass voltage VPASS4. At this time, in an embodiment, the intermediate selection line MSL22 may act similarly to the dummy word line DWL22 to alleviate the channel potential. As a result, in an embodiment, disturbance phenomenon may be effectively suppressed with only a small number of dummy word lines.

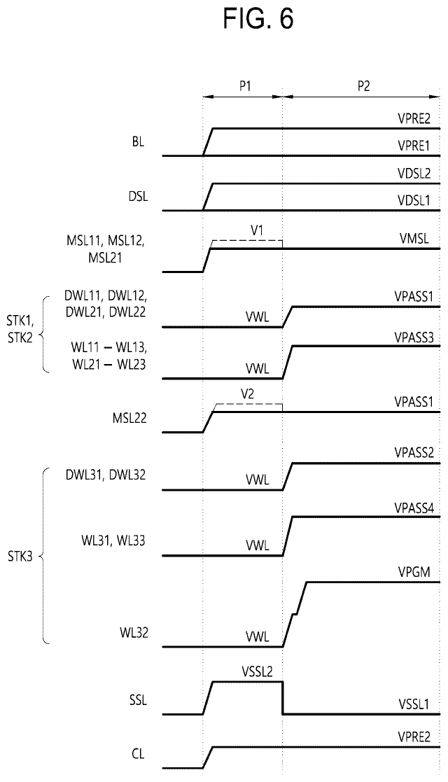

FIG. 6 is a timing diagram of a program operation in which the third stack STK3 is a selected stack as in the example of FIG. 5.

Referring to FIG. 6, a program operation may be performed similarly to the method described with reference to FIG. 4. Focusing on the parts that differ from the operation of FIG. 4, the intermediate selection voltage VMSL may be applied to the intermediate selection lines MSL11, MSL12, MSL21 adjacent to one or both ends of each of the non-selected stacks STK1, STK2. The intermediate selection voltage VMSL may be a voltage that turns off the intermediate selection transistors M211, M212, M221 included in the non-selected string ST2. Intermediate selection transistors M111, M112, M121 coupled to the intermediate selection lines MSL11, MSL12, MSL21 in the selected string ST1 may be turned on in response to the intermediate selection voltage VMSL. In an embodiment, a voltage V1 higher than the intermediate selection voltage VMSL may be applied to the intermediate selection lines MSL11, MSL12, MSL21 in a first interval P1.

Further, the first pass voltage VPASS1 may be applied to the intermediate selection line MSL22 adjacent to one end of the selected stack STK3. In an embodiment, a voltage V2 higher than the first pass voltage VPASS1 may be applied to the intermediate selection line MSL22 in the first interval P1.

In a second interval P2, the first pass voltage VPASS1 may be applied to the dummy word lines DWL11, DWL12, DWL21, DWL22 coupled to the non-selected stacks STK1, STK2. Additionally, a third pass voltage VPASS3 may be applied to the word lines WL11 to WL13, WL21 to WL23 coupled to the non-selected stacks STK1, STK2.

Additionally, the second pass voltage VPASS2 may be applied to the dummy word lines DWL31, DWL32 coupled to the selected stack STK3. Further, the fourth pass voltage VPASS4 may be applied to the remaining word lines WL31, WL33 that are not the target word line WL32 coupled to the selected stack STK3. Further, an intermediate voltage, e.g., the fourth pass voltage VPASS4, may be applied to the target word line WL32, and the program voltage VPGM may be applied after a predetermined time.

In an embodiment, when a selected stack is the first stack STK1, a program operation may be performed similarly to that described with reference to FIGS. 3 to 6.

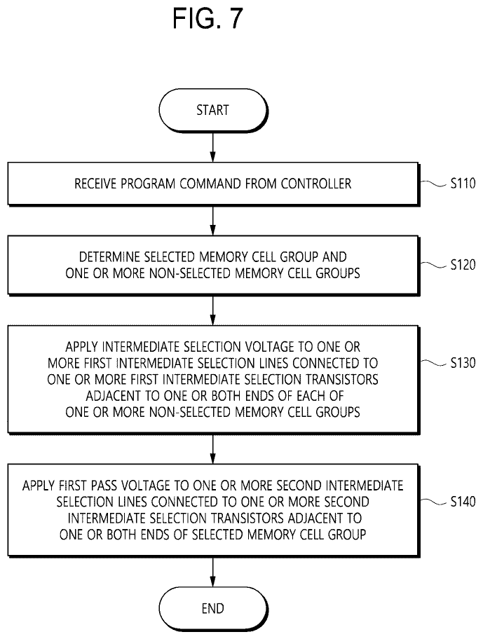

FIG. 7 is a flowchart illustrating operation of the memory device 100 according to an embodiment of the present disclosure.

Referring to FIG. 7, in operation S110, the control circuit 110 may receive a program command from a controller.

In operation S120, the control circuit 110 may determine, among memory cell groups included in a selected string, a selected memory cell group that includes a target memory cell in which a program operation is to be performed, and one or more non-selected memory cell groups that are not the selected memory cell group.

In operation S130, the decoder 123 may apply an intermediate selection voltage to one or more first intermediate selection lines coupled to one or more first intermediate selection transistors adjacent to one or both ends of each of the one or more non-selected memory cell groups. The intermediate selection voltage may be a voltage that turns off one or more third intermediate selection transistors included in one or more non-selected strings and coupled to one or more first intermediate selection lines, and turns on the first intermediate selection transistors.

In operation S140, the decoder 123 may apply a first pass voltage to one or more second intermediate selection lines coupled to one or more second intermediate selection transistors adjacent to one or both ends of the selected memory cell group. In an embodiment, the memory device 100 may include NAND Flash Memory, three-dimensional NAND Flash Memory, NOR Flash memory, Resistive Random Access Memory (RRAM), Phase-Change Memory (PRAM), Magnetoresistive Random Access Memory (MRAM), Ferroelectric Random Access Memory (FRAM), or Spin Transfer Torque Random Access Memory (STT-RAM).

Concepts are disclosed in conjunction with examples and embodiments. Those skilled in the art will understand that various modifications, additions, combinations, and substitutions are possible without departing from the scope and technical concepts of the present disclosure. The embodiments disclosed in the present specification should be considered from an illustrative standpoint and not a restrictive standpoint. Therefore, the scope of the present disclosure is not limited to the provided descriptions. All changes within the meaning and range of equivalency of the claims are included within their scope.

What is claimed is:

1. A memory device, comprising:
strings coupled between a bit line and a source line, each of the strings comprising a drain selection transistor coupled to the bit line, a source selection transistor coupled to the source line, a plurality of memory cell groups disposed between the drain selection transistor and the source selection transistor, and one or more intermediate portions disposed between the plurality of memory cell groups, each of the one or more intermediate portions including a plurality of intermediate selection transistors coupled in series between adjacent memory cell groups;
a control circuit configured to determine, among memory cell groups included in a selected string, a selected memory cell group that includes a target memory cell in which a program operation is to be performed, and one or more non-selected memory cell groups that are not the selected memory cell group, the selected string being a string that includes the target memory cell among the strings; and
a peripheral circuit configured to operate under control of the control circuit, configured to apply an intermediate selection voltage to one or more first intermediate selection lines coupled to one or more first intermediate selection transistors adjacent to one or both ends of each of the one or more non-selected memory cell groups, and configured to apply a first pass voltage to one or more second intermediate selection lines coupled to one or more second intermediate selection transistors adjacent to one or both ends of the selected memory cell group.

2. The memory device of claim 1, wherein:
the strings further include one or more non-selected strings other than the selected string;
the one or more non-selected strings include one or more third intermediate selection transistors coupled to the one or more first intermediate selection lines; and
the one or more third intermediate selection transistors are configured to turn off in response to the intermediate selection voltage.

3. The memory device of claim 2, wherein the one or more first intermediate selection transistors are configured to turn on in response to the intermediate selection voltage.

4. The memory device of claim 1, wherein the peripheral circuit is configured to apply the intermediate selection voltage at different levels to each of the one or more first intermediate selection lines.

5. The memory device of claim 1, wherein each of the plurality of memory cell groups include a plurality of memory cells coupled in series and one or more dummy memory cells disposed at one or both ends of the plurality of memory cells, and
wherein the peripheral circuit is configured to apply the first pass voltage to one or more first dummy word lines coupled to one or more first dummy memory cells included in the one or more non-selected memory cell groups.

6. The memory device of claim 5, wherein the peripheral circuit is configured to apply a second pass voltage higher than the first pass voltage to one or more second dummy word lines coupled to one or more second dummy memory cells included in the selected memory cell group.

7. The memory device of claim 1, wherein the peripheral circuit is configured to apply a third pass voltage higher than the first pass voltage to first word lines coupled to first memory cells included in the one or more non-selected memory cell groups.

8. The memory device of claim 7, wherein the peripheral circuit is configured to apply a fourth pass voltage higher than the third pass voltage to second word lines coupled to second memory cells that are not the target memory cell among memory cells included in the selected memory cell group.

9. The memory device of claim 1, wherein the peripheral circuit is configured to apply the intermediate selection voltage in a channel precharge interval and a program interval subsequent to the channel precharge interval, and configured to apply the first pass voltage in the program interval.

10. The memory device of claim 9, wherein the peripheral circuit is configured to apply a program voltage to a target word line coupled to the target memory cell in the program interval.

11. The memory device of claim 9, wherein the peripheral circuit is configured to:
in the channel precharge interval and the program interval, apply a first precharge voltage to one or more selected bit lines of a plurality of bit lines, apply a second precharge voltage to one or more non-selected bit lines of the plurality of bit lines, and apply the second precharge voltage to the source line,
in the channel precharge interval and the program interval, apply a drain selection voltage to a drain selection line coupled to drain selection transistors included in selected strings, and apply a drain non-selected voltage to drain selection lines coupled to drain selection transistors included in non-selected strings, the selected strings being strings that include target memory cells among a plurality of strings coupled to the plurality of bit lines, and the non-selected strings being strings other than the selected strings among the plurality of strings; and
apply a source selection voltage to a source selection line coupled to source selection transistors included in the plurality of strings in the channel precharge interval, and apply a source non-selected voltage to the source selection line in the program interval.

12. A memory device, comprising:
strings coupled between a bit line and a source line, each of the strings comprising a drain selection transistor coupled to the bit line, a source selection transistor coupled to the source line, a plurality of memory cell groups disposed between the drain selection transistor and the source selection transistor, and one or more intermediate portions disposed between the plurality of memory cell groups, each of the plurality of memory cell groups including a plurality of memory cells coupled in series and one or more dummy memory cells disposed at one or both ends of the plurality of memory cells, each of the one or more intermediate portions including a plurality of intermediate selection transistors coupled in series between adjacent memory cell groups;
a control circuit configured to determine, among memory cell groups included in a selected string, a selected memory cell group that includes a target memory cell in which a program operation is to be performed, and one or more non-selected memory cell groups that are not the selected memory cell group, the selected string being a string that includes the target memory cell among the strings; and
a peripheral circuit configured to operate under control of the control circuit, configured to apply an intermediate selection voltage to one or more first intermediate selection lines coupled to one or more first intermediate selection transistors adjacent to one or both ends of each of the one or more non-selected memory cell groups, and configured to apply a first pass voltage to one or more first dummy word lines coupled to one or more first dummy memory cells included in the one or more non-selected memory cell groups.

13. The memory device of claim 12, wherein:
the strings further include one or more non-selected strings other than the selected string;
the one or more non-selected strings include one or more third intermediate selection transistors coupled to the one or more first intermediate selection lines; and
the one or more third intermediate selection transistors are configured to turn off in response to the intermediate selection voltage.

14. The memory device of claim 13, wherein the one or more first intermediate selection transistors are configured to turn on in response to the intermediate selection voltage.

15. The memory device of claim 12, wherein the peripheral circuit is configured to apply the intermediate selection voltage at different levels to each of the one or more first intermediate selection lines.

16. The memory device of claim 12, wherein the peripheral circuit is configured to apply a second pass voltage higher than the first pass voltage to one or more second dummy word lines coupled to one or more second dummy memory cells included in the selected memory cell group.

17. The memory device of claim 12, wherein the peripheral circuit is configured to apply a third pass voltage higher than the first pass voltage to first word lines coupled to first memory cells included in the one or more non-selected memory cell groups.

18. The memory device of claim 17, wherein the peripheral circuit is configured to apply a fourth pass voltage higher than the third pass voltage to second word lines coupled to second memory cells that are not the target memory cell among memory cells included in the selected memory cell group.

19. The memory device of claim 12, wherein the peripheral circuit is configured to apply the intermediate selection voltage in a channel precharge interval and a program interval subsequent to the channel precharge interval, and configured to apply the first pass voltage in the program interval.

20. A memory device, comprising:
strings coupled between a bit line and a source line, each of the strings comprising a drain selection transistor coupled to the bit line, a source selection transistor coupled to the source line, a plurality of memory cell groups disposed between the drain selection transistor and the source selection transistor, and one or more intermediate portions disposed between the plurality of memory cell groups, each of the plurality of memory cell groups including a plurality of memory cells coupled in series and one or more dummy memory cells disposed at one or both ends of the plurality of memory cells, each of the one or more intermediate portions including a plurality of intermediate selection transistors coupled in series between adjacent memory cell groups;
a control circuit configured to determine, among memory cell groups included in a selected string, a selected memory cell group that includes a target memory cell in which a program operation is to be performed, and one or more non-selected memory cell groups that are not the selected memory cell group, the selected string being a string that includes the target memory cell among the strings; and
a peripheral circuit configured to operate under control of the control circuit, configured to apply a first pass voltage to one or more intermediate selection lines coupled to one or more intermediate selection transistors adjacent to one or both ends of the selected memory cell group, and configured to apply a second pass voltage higher than the first pass voltage to one or more dummy word lines coupled to one or more dummy memory cells included in the selected memory cell group.
